(19) United States
(12) Patent Application Publication
(10) Pub. No.: US 2007/0112529 A1
(43) Pub. Date: May 17, 2007

(54) Method for non-distructive measurement or comparison of a laser radiation content in optical components

(75) Inventors: Janick Bigarre, Tours (FR); Patrick Hourquebie, Esvres Sur Tondre (FR); Ludovic Doucet, Villaines Les Rochers (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQE, Paris 15eme (FR)

(21) Appl. No.: 10/580,822

(22) PCT Filed: Nov. 27, 2003
(86) PCT No.: PCT/FR03/50140

§ 371 Date: May 26, 2006

(51) Int. Cl. G01R 31/00

(52) U.S. Cl. 702/59

(57) ABSTRACT

A predictive choice process of a manufacturing process of an optical component intended to be subjected to laser fluxes, the choice being intended to select from among several possible manufacturing processes that which results in components having better laser flux behaviour than those obtained by the other possible processes characterised in that a) a number N of cathodoluminescence measurements are made on components obtained by a first of the possible manufacturing processes, while the component receives an electronic beam having a determined energy, a focus on the surface of the determined component and a determined intensity controlled by a value of a ground current measured on the component, while it is being subjected to said electronic beam, b) an average cathodoluminescence value on the N measurements is calculated, c) operations a) and b) on components obtained by each of the other possible manufacturing processes are repeated, d) the most advantageous manufacturing process is decided as the one for which the average cathodoluminescence value is the lowest.

### TECHNICAL FIELD

The invention relates to the field of non-destructive processes for measuring or comparing the laser flux behaviour of optical components.

### PRIOR ART

The passage of a strong laser flux through the components of the chain of a very high-power laser (laser glasses, polarisers, mirrors, thin layers, crystals, cabin windows, etc.), or more generally of any optical component, causes the appearance of volume or surface damage to the components which progressively degrade the characteristics of the beam.

The laser flux behaviour of the materials making up optical components is determined generally by taking laser shots at a sample and noting the variation in certain optical parameters (diffusion, absorption . . . ) or by directly observing the appearance of microscopic volume or surface damage of the materials. These measurements or observation help determine possible damage and determine whether or not the sample is suitable to support a laser flux of determined surface power.

Several modes of laser shots can be utilised. The standard NF EN ISO 11254 defines two of these modes which are the most often utilised. According to a first mode the power between two shots at the same point is progressively increased until damage appears. The advantage of this mode is to limit the number of points necessary to obtain a good statistic. However, it generates a conditioning phenomenon, whereof the origin is not well known, which has a tendency to increase the flux behaviour. According to a second mode a single shot unique is taken per point at a given power, then the number of damaged sites is determined. This gets away from the phenomenon of conditioning, but requires a greater number of measuring points. The result thus depends on numerous parameters (measuring mode, wavelength of the laser, duration of the pulse, spot surface . . . ) which are sometimes difficult to manage. In spite of the definition of some international standards, such as for example the standard NF EN ISO 11254 for each of the two methods mentioned hereinabove, the results of flux behaviour are difficult to compare from one test bank to the other. Also, it should be understood that they are always given in terms of probability.

These measurements are destructive since the threshold of damage must be exceeded in order to determine the flux behaviour.

Due to the fact that the known method is destructive, the measured value of the laser flux behaviour is the real behaviour value only if the optical components of a series of productions are sufficiently homogeneous for the assays conducted on a sample to be representative of what is obtained from the remainder of the components of the series. It can be necessary, for example during changing batches, to repeat characterisation measurements.

### DESCRIPTION OF THE INVENTION

The faults engendered in the sub-layer by the polishing processes of the optical components produce notable drop in laser flux behaviour by absorbing the photons and trapping electrons and holes. These faults can be fissures terminating at the surface of incidence, metallic inclusions but likewise localised faults (oxygen gaps, liaison rupture, atomic impurities . . . ). The study of such localised faults is very delicate since the perturbed layer is extremely fine (of the order of several micrometers) and the faults are not observable by surface measuring techniques. When determining laser damage, in terms of the surface, it is a question of the surface as such and of the volume situated immediately under the surface, down to a depth which can reach several micrometers. The depth concerned is itself a function of the surface density of power of the laser to which the surface is going to be subjected.

The aim of the process according to the invention is to solve these problems of determining the flux behaviour of a component having an incident surface for receiving radiation, in particular laser, by taking non-destructive measurements on this component. The measurements are representative of the resistance of the component to damage during reception of a laser flux. For this, a study is made directly of the incident surface of the radiation of the component itself and more particularly the faults which are at the origin of the appearance of the damage.

The object of the present invention is thus a non-destructive verification process of laser flux behaviour of an optical component, from a quantitative measurement representative of the density of the faults of a surface of a material, this surface making up the incident surface of a laser flux applied to the component. Because the measurement is non destructive, the components can be tested as needed on a specific basis, thus ensuring quality production. The measurement can also be made on a sample basis, on each of the production batches according to statistical techniques of the choice of the percentage of samples tested, known per se in quality control. The measurement of behaviour is not actuated, as in the prior art, but measured.

According to the invention an electron beam of controlled energy and intensity is used to locally excite the material and the surface of the component to be studied is scanned with this electron beam. The depth of excitation depends on the energy of the electron beam. This is how it is possible to determine the distribution of the faults in the thickness of the material in the vicinity of the incident surface.

In the excited zone, the interaction between the electron beam and the localised faults produces, according to a known phenomenon, luminescence called cathodoluminescence, and trapping of charge carriers. This phenomenon is explained as follows. After a period of strong mobility, the carriers excited by the beam are trapped at the level of localised faults and produce in certain cases the phenomenon of cathodoluminescence. This trapping of electrons on these faults creates coloured centres which emit photons the wavelength of which depends on the nature of the fault constituting the trap and on the environment of the coloured centre.

In addition, trapping the charge carriers (electrons and holes) triggers a variation in ground current and secondary electronic emission. This helps detect the presence of faults which do not produce coloured centres and which are thus not luminescent. This process likewise enables to obtain non-destructive and finer measurement. Measuring the ground currents helps render quantitative the measuring of faults, as it allows the intensity of the electronic beam to be controlled at the precise moment of measuring.

According to the invention simultaneously the cathodoluminescence is measured by means of an optical spectrometer and the trapping of the electric carriers from the ground currents.

Due to coupling of the two types of measurements, ground current and cathodoluminescence, the excitation conditions of the material are controlled perfectly and all the faults likely to contribute to the appearance of damage when the material is subjected to a strong laser flux are taken into account. The linking of the two measurements creates quantitative profiles of the rates of faults in the first micrometers of the material, which cannot currently be achieved with any other technique.

Therefore utilisation of the process according to the invention for example allows a manufacturing process to be selected as being a priori better than another. This means that it can be determined that the components made according to one of the processes will have a probability of resisting a laser flux greater than that of the components obtained by the other manufacturing process.

This process can thus be applied for optimisation of the different preparation phases of a component with a view to improving its flux behaviour: nature and design process of materials, surface polishing and treatment process, conditioning, curing and stabilisation of damage . . . It can likewise be utilised for following up on the ageing of the components in light of their preventive maintenance. It can likewise be used for the quality control of optical components.

Therefore, according to a first application the invention is relative to a predictive choice process of a manufacturing process for an optical component to be submitted to laser fluxes, the choice being intended to select from among several possible manufacturing processes the one which results in components having better laser flux behaviour than those obtained by the other possible processes, characterised in that

a) a whole number N of measurements of cathodoluminescence is made on components obtained by the first of the possible manufacturing processes, while the component receives an electronic beam having a determined energy, focussing on the surface of the determined component and a determined intensity controlled by a value of ground current measured on the component while it is subjected to said electronic beam,

b) an average cathodoluminescence value on the N measurements is calculated,

c) operations a) and b) are repeated on components obtained by each of the other possible manufacturing processes,

d) it is decided that the most advantageous manufacturing process is that for which the average cathodoluminescence value is the weakest.

According to a variant of the process, steps a) to c) are repeated for different energy values of the electronic beam, a histogram of the average values of cathodoluminescence is established for each of the energies,

in calculating the average cathodoluminescence value integration of the cathodoluminescence values on the different energies of electronic beams is taken into account.

In a second application the invention relates to a control process of a state of a surface of an optical component intended to be an incident surface of a laser beam, so as to determine whether said surface has a default density which is less than a default density beyond which the optical component is likely to be damaged by submission to a laser flux having a power (flux density) at most equal to a predetermined threshold for a maximum predetermined duration, characterised in that

a) samples are made of said optical component by the same manufacturing process, in particular with respect to the state of said incident surface and they are separated into first and second samples,

b) in an earlier calibration phase on the first samples correlation is made between cathodoluminescence values obtained in conditions of determined electronic shots, and laser flux behaviour of the first samples, this correlation helping to determine one or more cathodoluminescence thresholds, each threshold corresponding to behaviour conditions of the first samples to laser flux, a component having a cathodoluminescence value less than one of the thresholds being acceptable for the behaviour conditions having lead to this threshold, and rejected for these conditions in the opposite case,

c) the cathodoluminescence value produced is measured on a second sample by electronic shots taken in the same conditions as in step b), the component is accepted for all the behaviour conditions corresponding to thresholds greater than the value measured, and it is rejected for all the behaviour conditions corresponding to threshold less than the value measured.

d) the step c) is repeated on other second samples on a specific basis or by sampling.

### BRIEF DESCRIPTION OF THE DIAGRAMS

The invention will now be described by means of the attached diagrams, in which:

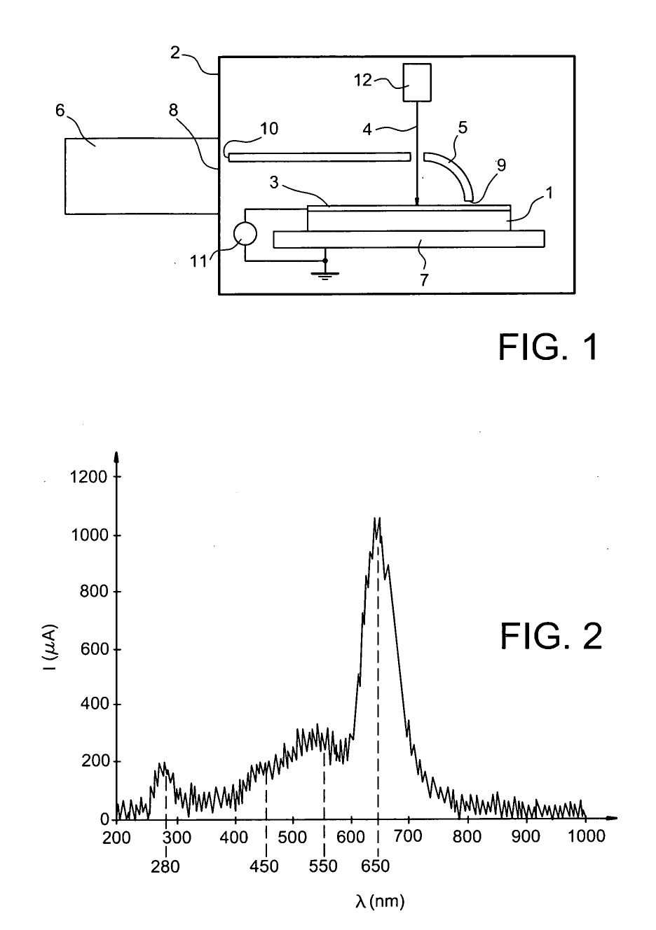

FIG. 1 illustrates an example of a device for simultaneously obtaining measurements of cathodoluminescence, electronic secondary emission current and ground current.

FIG. 2 illustrates an example of the cathodoluminescence spectrum,

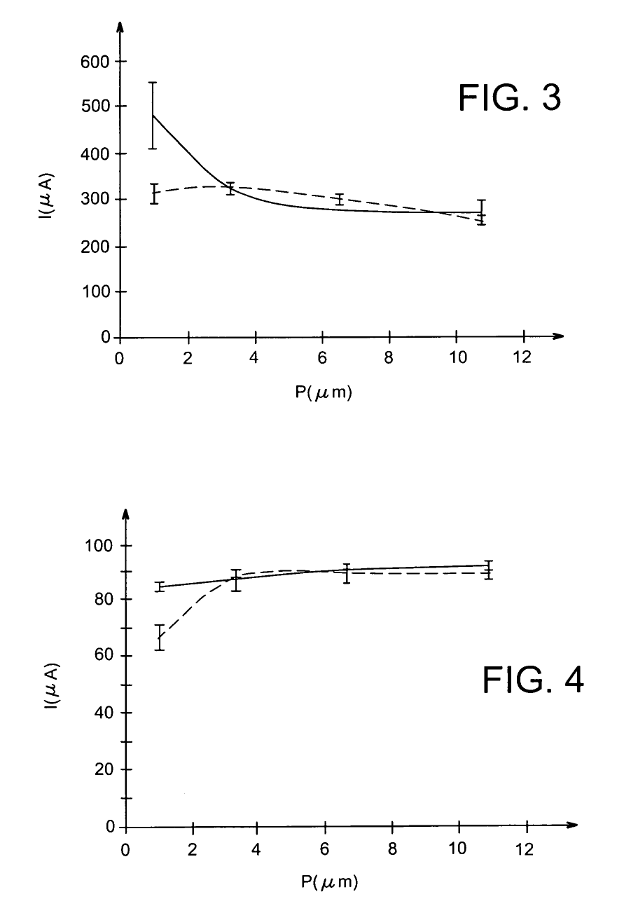

FIGS. 3 and 4 are graphics which give the cathodoluminescence value and thus the density value faults corresponding to the wavelengths 650 and 550 nm respectively, as a function of the depth for samples 1 and 2. The curves corresponding to sample 1 and to sample 2 are in full lines and in dotted lines respectively.

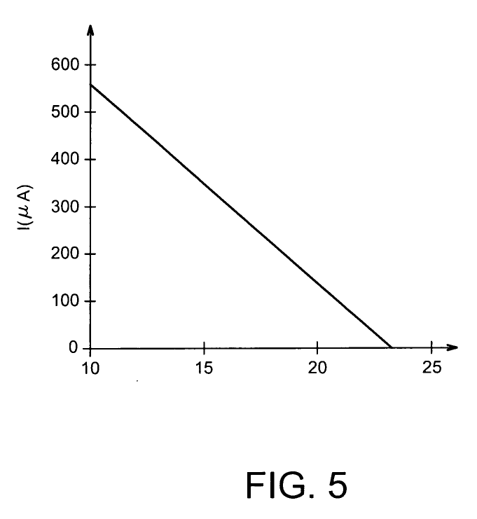

FIG. 5 illustrates a correlation line between the laser flux behaviour of a component illustrated in abscissa and the cathodoluminescence value obtained under the conditions of determined electronic shots represented in ordinates.

### DETAILED DESCRIPTION OF PARTICULAR EMBODIMENTS

In reference to FIG. 1, a device according to the invention comprises an empty enclosure 2 making up the measuring chamber. An electron gun 12 fitted with control means of the direction of emission of the beams, known per se is arranged inside the empty enclosure 2. This can be for example an electron scanning microscope 12 or any other device having an electron gun. A metallic sample holder 7 connected to ground is placed in the empty enclosure 2 such that it can receive an electron beam 4 emitted by the electron gun 12. The empty enclosure 2 also contains a device 5 allowing photons emitted by a component placed on the sample holder 7 to pass through a wall 8 of the empty enclosure 2. It can for example be an optical guide having a first end 9 controlled by scanning means and a second end facing the wall 8. The device according to the invention is complemented by an optical spectrometer 6 functioning especially in the UV and the visible ranges between 180 and 1000 nm. The optical spectrometer 6 is placed so as to receive radiation originating from the second end 10 of the optical guide 5. Finally, a galvanometer 11 connected on one side to ground and having another terminal which can be connected to a conductive surface of a component to be measured completes the measuring device.

It operates as follows.

The surface of the sample is preferably metallised by means of a conductive deposit 3, for example gold, attached to ground so as to eliminate superficial charges. This conductive deposit 3 is intended to allow displacement of the charges and thus measuring of the displacement current by the galvanometer 11. The conductive deposit 3 is not indispensable. The material can likewise be studied non-metallised. In this case, a value representative of the trapped charges is measured by measuring a current image in the metallic support 7. In this case, the effect of the charges which progressively decreases the surface potential under the beam must be considered. If the sample is not metallised, it is possible likewise to use a pressure of several Pascals in the empty enclosure so as to neutralise the surface charges and avoid the charge effect.

A volume is excited in the vicinity of the incident surface of the component or of a material to be included in the component by injecting electrons by means of the beam 4 produced by the gun 12. The energy, the intensity and the focus of this beam are controlled. So that the process is non-destructive, it is necessary for the electron beam not to create supplementary faults. For this, the current density and the dose of electrons introduced must be sufficiently low. The duration of excitation must be controlled precisely so as to manage the quantity of electrons injected into the material. An initial measurement of the ground currents helps to perfectly understand the intensity of the beam. It is necessary to have precise control means of the irradiated surface, that is, of the focus of the electronic beam, so as to manage the current density. This produces quantitative and reproducible measurements.

During injection of the electrons, the photons emitted are collected by the device 5 allowing the photons to pass through the wall 8 of the chamber 2. The photon emissions are sent to a photon sensor transforming the received photons into a charge or current value. Simultaneously, the ground current is measured at the level of the sample holder 7 connected to ground.

On completion of measuring, for each measuring point on the material, a value of the global photon emission, and a value of the ground current are obtained. The value of the ground current is intended to retroact on the electron gun so as to keep the intensity of the electronic beam constant and reproducible throughout the measuring duration.

A first example of use of the process according to the invention concerns the effect of polishing on the distribution of the faults in the thickness.

Two samples of natural molten silicon were polished using the same polishing process. The first (sample 1) was left as such and the second (sample 2) underwent additional ionic abrasion of a few micrometers. They were metallised by means of a deposit of gold. Cathodoluminescence measurements were made at different beam energies. Each value corresponds to an average of five measurements made on different zones.

FIG. 2 shows a spectrum characteristic of the cathodoluminescence of sample 1. The presence of four peaks which can be associated with three types of faults in the material of sample 1 are noted. The cathodoluminescence peaks are at wavelengths of 280, 450, 550, and the highest peak is 650 nanometres.

FIGS. 3 and 4 give the distribution of the faults corresponding to the wavelengths 650 and 550 nm respectively, as a function of the depth for samples 1 and 2.

It is known that the maximum depth of penetration of the electrons can be calculated by means of an empirical law:
For an energy E0<10 keV R=90 ρ^{0, 8} E₀¹³ (1)
For an energy E0>10 keV R=45 ρ^{0, 9} E₀¹⁷ (2)

In formulae (1) and (2) above R is the depth of penetration and ρ is the density of the material examined. It is evident that the depth of penetration could be regulated by adjusting the energy of the electronic beam. This energy of the electronic beam is representative of the depth of the superficial layer examined.

It is evident that the additional ionic abrasion treatment undergone by sample 2 has helped diminish the density of the faults which had been generated near the surface by polishing.

This translates by the fact that in FIG. 3, which measures the default density producing significant radiation at a wavelength of 650 nm, the cathodoluminescence current of the sample 1 illustrated by a curve in full lines is at a value higher than that of sample 2 represented by a curve in dotted lines, for energies of the electronic beam corresponding to investigation depths of the faults of between approximately 0.8 and 3 μm. For depths greater than 3 μm, the fault densities producing cathodoluminescence of 650 nm are substantially the same. The same applies in FIG. 4 for the faults producing significant radiation at a wavelength of 550 nm

The process according to the invention thus measures the effect of polishing and post-polishing treatments on the default densities in the sub-layer and thus optimises the polishing processes so as to decrease the default densities generated. In this first example it is about application of the process according to the invention, predictive measurements of the laser flux behaviour. These measurements decide, without having to take laser shots and without destroying the samples, that one embodiment is better than another.

A second example of application of the process according to the invention relates to the establishment of a correlation between the cathodoluminescence intensity and the laser flux behaviour.

Three samples of natural molten silicon were made. Each sample corresponds to a different polishing quality which results in a priori different flux behaviours. The values of flux behaviour of each sample were determined by a destructive technique by taking laser shots. These measurements were taken according to known techniques.

The samples were then metallised by means of a gold deposit. Cathodoluminescence measurements were then taken as pointed out hereinabove. Each cathodoluminescence value corresponds to an average of five measurements made on different zones.

The evolution of the cathodoluminescence intensity as a function of the flux behaviour measured by damage laser is shown in FIG. 5. This is a negative sloping line. It is seen that the flux behaviour is inversely proportional to the cathodoluminescence intensity with a good correlation coefficient.

A third embodiment of the invention will now be described.

In this embodiment the process according to the invention is utilised for quality control of production of an optical component, in particular a surface state of this component. This surface is intended to be an incident surface of a laser beam. It is a question of determining whether said surface has a default density which is less than a default density beyond which the optical component is likely to be damaged by being subjected to a laser flux having a power (flux density) at most equal to a predetermined threshold for a maximum predetermined duration. Here, likely to be damaged means a probability greater than a given threshold. And for a maximum predetermined duration can also be about a predetermined number of laser pulses.

According to this embodiment of the process, a set of samples separated into a first series of samples which will act as standards and into a second series which will be the production components. The first samples are submitted to laser shots, then to cathodoluminescence measurements so as to establish a correlation between the behaviour with damage laser and the cathodoluminescence value. This first series of samples is intended to be sacrificed since it will have undergone damage. This correlation defines a cathodoluminescence threshold value below which the components are acceptable and above which they must be rejected. Cathodoluminescence measurements verifying whether or not the sample must be rejected are then made on the second series of samples intended for production.

The first step of the process which consists of making a correlation between a cathodoluminescence threshold value and a flux behaviour value can be made in different known manners. The essential aspect during this preliminary step is that a threshold value of default density and a cathodoluminescence value are correlated.

A description will be given hereinafter of the ways and variants of these manners of taking the preliminary correlation step, in which laser shots and shots of electronic beams for measuring cathodoluminescence are made.

The samples are in general made on a wafer of the order of tens of cm in diameter. A plurality of laser shots at different powers is taken in zones spaced apart from one another, for example 3 mm. Each shot zone has a diameter of the order of one or more μm. The laser shot zones and zones without laser shots are examined to determine parameters for determining a default density in a manner known per se. In particular it is examined as to whether or not there is any damage making the examined zone unsuited to the use foreseen. The laser shots can be taken according to one or the other of the methods described hereinabove in relation to the prior art. The values of power and the default density on the zones not having been subjected to shots and on the zones which have been subjected to laser shots are recorded.

The material is then metallised to effect, as indicated hereinabove, cathodoluminescence measurements on zones not having been subjected to laser shots and on the zones damaged which have been subjected to laser shots. The cathodoluminescence measurements are taken for the same energy of the electronic beam, and for the same intensity controlled by the value of the ground current.

According to a first manner of creating the correlation between the damage and the cathodoluminescence value the correlating line, the cathodoluminescence energy and the default density are traced. This correlation line is similar to that shown in FIG. 5.

As a function of the values of default densities quantified by cathodoluminescence values, a decision is made on an unacceptable value of default densities beyond which the component having a default density and thus a measured cathodoluminescence value greater than a threshold value will be rejected.

Therefore, according to this embodiment of the process,

samples of an optical component are produced by the same manufacturing process, in particular with respect to the state of the incident surface,

fault densities are determined on zones of first samples having been subjected to laser shots of powers different to one another and on zones not having been subjected to shots,

shots of electronic beams of intensity controlled by measuring the ground current are taken on zones having been subjected to laser shots, and on zones not having been subjected thereto, the different electronic shots having the same electronic energy and the same intensity, and the cathodoluminescence values are measured,

A line is traced correlating the default density and the cathodoluminescence value,

A threshold or several fault thresholds, and correlatively cathodoluminescence thresholds beyond which the component must be rejected for a given application, are determined by means of the line and the effects of the fault densities on the aptitude of the component to withstand the laser flux to which it must be subjected.

According to a variant of the first production method of the preliminary phase for determining a threshold cathodoluminescence value, an energy value of the electronic beam which will be the most appropriate for conducting measurements is also determined.

It is evident hereinabove that the inventors have ascertained that there was a linear relation between the cathodoluminescence value, itself representative of the default density, and the laser flux behaviour. An example of such a relation is shown on the graphic already mentioned in FIG. 5. This graphic shows that the laser flux behaviour, carried in abscissa, decreases proportionally to the value of the cathodoluminescence carried in ordinates. This graphic is drawn for a given depth, for a given material. It is likewise evident from hereinabove that there is a relation between the energy of the electronic beam and the depth of investigation of the faults. Because of this, for different energies of the electronic beam, and with the conditions of intensity of the beam and focus on the material also being identical, different lines are obtained, each having a slope. According to this variant embodiment, the cathodoluminescence measurements resulting in the linear correlation between the default density and the cathodoluminescence value are repeated. Several correlation lines are thus obtained, each corresponding to an energy of the electronic beam. According to this variant, the threshold value is determined from the correlation line corresponding to the electronic beam energy for which the slope allows good discrimination of the flux behaviour as a function of the default densities. This is about the line with the greatest slope, in absolute slope value, the value of the slope being negative.

A second way of creating the previous correlation step between a threshold cathodoluminescence value and a greater threshold value of acceptable default density will now be described.

b21) The surface of incidence of the first samples of said optical component taken among the samples made in step a) is subjected to a shot of an electronic beam having known energy and intensity, the intensity being controlled by measuring the ground current of said sample subjected to the shot of said electronic beam,

b22) While each of said optical components is subjected to the shot of the electronic beam, apart from the ground current to apply it to the instantaneous control of the intensity of the electronic beam, the cathodoluminescence intensity of said optical component is measured,

b23) The value of the cathodoluminescence intensity is recorded for each of the samples processed by an electronic beam of the same energy and same intensity,

b24) The first samples are sorted in ascending order of default densities, the samples having the fewest faults being those for which the value of the cathodoluminescence intensity is the lowest,

b25) The first samples are submitted to laser flux having the maximum threshold power for which the components are provided, and for a duration equal to the maximum duration during which the optical components must receive this flux without undergoing any damage,

b26) The highest N cathodoluminescence intensities are taken from the components subjected to the flux in step b25) and which have not undergone any unacceptable damage, and it is decided that a maximum cathodoluminescence intensity calculated from a linear combination of these N cathodoluminescence intensities is the maximum acceptable cathodoluminescence intensity measured for said optical components.

In an embodiment allowing selective sorting of the components as a function of different usages of the component, several cathodoluminescence thresholds are determined. Therefore, a first threshold, the smallest cathodoluminescence value corresponds to components having the lowest default density. The components having a cathodoluminescence value less than this first threshold could be sorted into a first quality category. The components having a cathodoluminescence value greater than this first threshold but less than a second threshold could be sorted into a second category and so on until there is a whole number P of categories of component qualities.

It should be noted that each of the sets of measurements enabling a point in space, cathodoluminescence energy, flux behaviour, to be determined is produced over a large number of points of the material, the points of space thus being representative average values.

Statistical processing is then carried out to determine an average power value for which there is a damage probability greater than a predetermined threshold. Therefore, in terms of a laser power threshold for which there is damage, it should be understood that this is a threshold for which the probability of damage is higher than a predetermined threshold. Naturally, according to the certainty of preferred non damage, the threshold of probability will have a more or less high value.

1) A predictive choice process of a manufacturing process of an optical component intended to be subjected to laser fluxes, the choice being intended to select from among several possible manufacturing processes that which results in components having better laser flux behaviour than those obtained by the other possible processes, characterised in that
a) a number N of measurements of cathodoluminescence are made on components obtained by a first of the possible manufacturing processes, while the component receives an electronic beam having a determined energy, a determined focusing at the surface of the component and a determined intensity controlled by a value of a ground current measured on the component, while it is being submitted to said electronic beam,
b) an average cathodoluminescence value on the N measurements is calculated,
c) operations a) and b) on components obtained by each of the other possible manufacturing processes are repeated,
d) the most advantageous manufacturing process is decided as the one for which the average cathodoluminescence value is the lowest.

2) The process as claimed in claim 1, characterised in that steps a) to c) for different energy values of the electronic beam are repeated, and in that a histogram of the average cathodoluminescence values for each of the energies is established,
in calculating the average cathodoluminescence value an integration of the cathodoluminescence values on the different energies of electronic beams is taken into account.

3) A process for controlling a state of a surface of an optical component intended to be a surface of incidence of a laser beam, so as to determine whether said surface has a default density which is less than a default density beyond which the optical component is likely to be damaged by submission to a laser flux having a power (flux density) at most equal to a predetermined threshold for a maximum predetermined duration, characterised in that
a) samples of said optical component are produced by the same manufacturing process, in particular as concerns the state of said incident surface, and they are separated into first and second samples,
b) in a preliminary calibration phase a correlation between cathodoluminescence values obtained in conditions of determined electronic shots, and laser flux behaviour of the first samples is made on the first samples, this correlation helping to determine one or more cathodoluminescence thresholds, each threshold corresponding to behaviour conditions of the first samples to laser flux, a component having a cathodoluminescence value less than one of the thresholds being acceptable for the behaviour conditions having resulted in this threshold, and rejected for these conditions in the opposite case,
c) the cathodoluminescence value produced on a second sample is measured by electronic shots taken in the same conditions as in step b), the component is accepted for all the behaviour conditions corresponding to thresholds greater than the value measured, and is rejected for all the behaviour conditions corresponding to thresholds less than the value measured.
d) step c) is repeated on other second samples on a specific basis or by sampling.

4) The process as claimed in claim 3, characterised in that to carry out step b)
b11) fault densities are determined on zones of the first samples having been subjected to laser shots of powers different to one another and on zones not having been subjected to shots,
b12) shots of electronic beams of intensity controlled by measuring the ground current, the different electronic shots having the same electronic energy and the same intensity, are made on the zones having been subjected to laser shots and on the zones not having been subjected thereto, the cathodoluminescence values are measured,
b13) a line is traced correlating the default density and the cathodoluminescence value,
b14) a threshold or several fault thresholds, and correlatively cathodoluminescence thresholds beyond which the component must be rejected for a given application, is determined by means of the line and the effects of the fault densities on the aptitude of the component to withstand the laser flux to which it must be subjected.

5) The process as claimed in claim 4, characterised in that to carry out step b)
b15) steps b12 and b13 are repeated for different energy values of the electronic beam,
and in that in step b14)
the threshold value is determined from the line of greatest slope, in absolute value.

6) The process as claimed in claim 3, characterised in that to carry out step b)
b21) a surface of incidence of first samples of said optical component is subjected to shots of electronic beams having different energies and the same known intensity, the intensity being controlled by measuring the ground current of said sample subjected to the shot of said electronic beams,
b22) while each of said optical components is subjected to the shot of an electronic beam, apart from the ground current to be applied to the instantaneous control of the intensity of the electronic beam, the cathodoluminescence intensity of said optical component is measured,
b23) the value of the cathodoluminescence intensity is recorded for each of the samples processed by an electronic beam of the same energy and same intensity,
b24) the first samples are sorted by ascending order of default densities, the samples having the fewest faults being those for which the value of the cathodoluminescence intensity is the lowest,
b25) the first samples are subjected to laser flux having the maximum threshold power for which the components are provided, and for a duration equal to the maximum duration during which the optical components must receive this flux without undergoing any damage,
b26) the N highest cathodoluminescence intensities are taken from the components subjected to flux at step b25) and which have not undergone any damage, and it is decided that a maximum cathodoluminescence intensity calculated from a linear combination of these N cathodoluminescence intensities is the intensity of maximum acceptable cathodoluminescence measured for said optical components.
